(19) United States
(12) Patent Application Publication
(10) Pub. No.: US 2025/0349589 A1
(43) Pub. Date: Nov. 13, 2025

(54) COMPUTER VISION FOR SUSCEPTOR LEVELING AND ALIGNMENT

(71) Applicant: Applied Materials, Inc., Santa Clara, CA (US)

(72) Inventor: Aniketnitin PATIL, San Jose, CA (US)

(21) Appl. No.: 18/662,802

(22) Filed: May 13, 2024

(51) Int. Cl. H01L 21/68; G05B 13/02; G05B 19/402

(52) U.S. Cl. CPC H01L 21/681; G05B 13/0265; G05B 19/402

(57) ABSTRACT

Methods and devices for aligning a susceptor are provided herein. Embodiments include creating a three-dimensional (3D) map of a susceptor and a ring within a substrate processing chamber based on camera data comprising image data associated with the susceptor and the ring. Embodiments further include adjusting a position of the susceptor based on the 3D map to create a gap having a target size between the susceptor and the ring.

### BACKGROUND

### Field

Embodiments of the present invention generally relate to semiconductor processing and, more specifically, to a machine learning-based process for positioning a substrate inside a processing chamber using a generated three-dimensional representation of a susceptor and a processing chamber ring.

### Description of the Related Art

Semiconductor substrates are processed for a wide variety of applications, including the fabrication of integrated devices and microdevices. One method of processing substrates includes growing an oxide layer on an upper surface of the substrate within a processing chamber. The oxide layer may be deposited by exposing the substrate to oxygen and hydrogen gases while heating the substrate with a radiant heat source. The oxygen radicals strike the surface of the substrate to form a layer, for example a silicon dioxide layer, on a silicon substrate.

In substrate processing systems, a substrate may be transported from a substrate load lock chamber to a process chamber with a transport robot for processing. The transport robot may use a substrate support (e.g. susceptor) for holding a substrate inside a processing chamber. One of the challenges of substrate handling and positioning is the need to align the support and the substrate inside the processing chamber to ensure optimal processing. As an example of the importance of alignment accuracy, if the substrate is misaligned within the chamber (e.g., too close to a heating element within the chamber or tilted relative to a heating element), local temperature changes occur, resulting in temperature gradients across the substrate. This can cause non-uniformity in process results.

Current methods for aligning a susceptor within a processing chamber may involve manually calibrating a transport robot to position the susceptor. Such manual calibration may require an extensive amount of time while also being prone to manual errors. Methods of automating the alignment and calibration process may involve using positional data from sensors to determine the position of the susceptor relative to the processing chamber. However, these methods may fail to provide a fully accurate representation of the position of the susceptor. As a result, existing techniques for alignment of a susceptor may require gathering additional positional data and making adjustments each time a substrate is inserted into the processing chamber, resulting in delays.

Therefore, there is a need for improved susceptor alignment techniques that provide for more efficient and accurate alignment.

### SUMMARY

Embodiments described herein generally relate to aligning a susceptor within a substrate processing chamber, and more particularly, to generating a three dimensional (3D) map of a susceptor and a ring within the processing chamber and then adjusting the position of the susceptor based on the 3D map.

In one embodiment, a method comprises creating a three-dimensional (3D) map of a susceptor and a ring within a substrate processing chamber based on camera data comprising image data associated with the susceptor and the ring; and adjusting a position of the susceptor based on the 3D map to create a gap having a target size between the susceptor and the ring.

In another embodiment, a method comprises creating a three-dimensional (3D) map of a susceptor and a ring within a substrate processing chamber by: receiving camera data comprising image data and depth data associated with the susceptor and the ring; creating the 3D map based on the camera data using a machine learning model trained, based on position data from a two-dimensional (2D) profilometer indicating a location of the susceptor relative to the ring, to create 3D maps; adjusting the position of the susceptor; receiving additional position data from the 2D profilometer; receiving additional camera data; and retraining the machine learning model using the additional position data, wherein the retrained machine learning model is used to update the 3D map; and adjusting the position of the susceptor based on providing the 3D map to an optimization algorithm to create a gap having a target size between the susceptor and the ring.

In another embodiment, processing chamber system configured for susceptor alignment comprises a processing chamber for processing substrates; a camera system configured to capture image data and depth data; a two-dimensional (2D) profilometer; a susceptor configured to hold a substrate; and a computing device capable of: creating a three-dimensional (3D) map of a susceptor and a ring within a substrate processing chamber based on camera data comprising image data associated with the susceptor and the ring and position data from a two-dimensional (2D) profilometer; and adjusting a position of the susceptor based on the 3D map to create a gap having a target size between the susceptor and the ring.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 depicts an example substrate processing system according to certain embodiments.

FIG. 2 depicts an example of computing components for susceptor alignment.

FIG. 3 depicts an example of views of a susceptor relative to a ring of a processing chamber according to certain embodiments.

FIG. 4 is a flow diagram of example operations for aligning a susceptor within a substrate processing chamber, according to certain embodiments

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to aligning a susceptor within a substrate processing chamber. More particularly, embodiments described herein provide devices and methods for aligning a susceptor within a substrate processing chamber.

Embodiments described herein provide for creating a three dimensional (3D) map of a susceptor and a ring within a substrate processing chamber based on data received from a camera system and a two-dimensional (2D) profilometer. The position of the susceptor may then be adjusted based on the 3D map, such as by using an optimization algorithm or machine learning techniques.

Embodiments described herein incorporate a camera system that is configured to capture both image data and depth data. The image and depth data are used along with the positional data received from the profilometer to generate the 3D map. For example, a neural network may be trained through a supervised learning process using the 2D profilometer data as ground truth to generate a 3D map based on the image and depth data. The susceptor may be moved (e.g., manually or automatically) and additional image, depth, and positional data may be obtained. The neural network may be retrained based on the additional data, and an updated 3D map may be created. Once a 3D map that provides an accurate representation of how susceptor positional adjustments impact the position of the susceptor relative to the ring is generated, an optimization algorithm or a machine learning process may be used to adjust the susceptor into a position specified by a user.

### Example Processing Chamber Configured for Susceptor Alignment

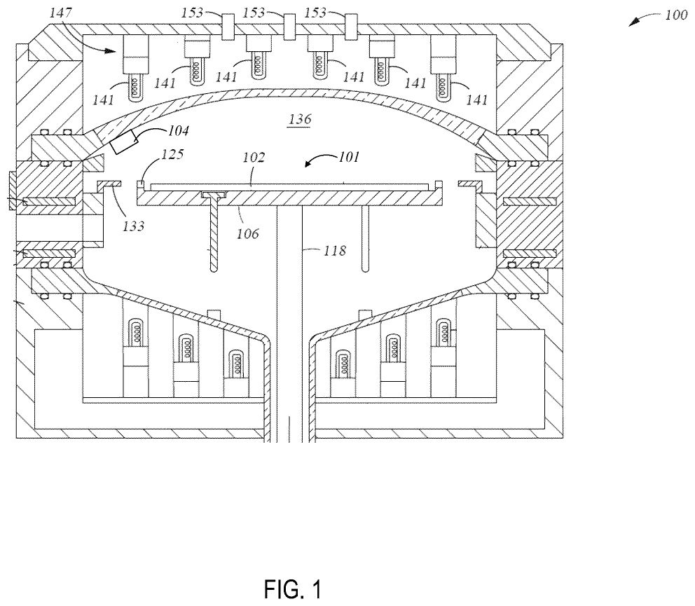

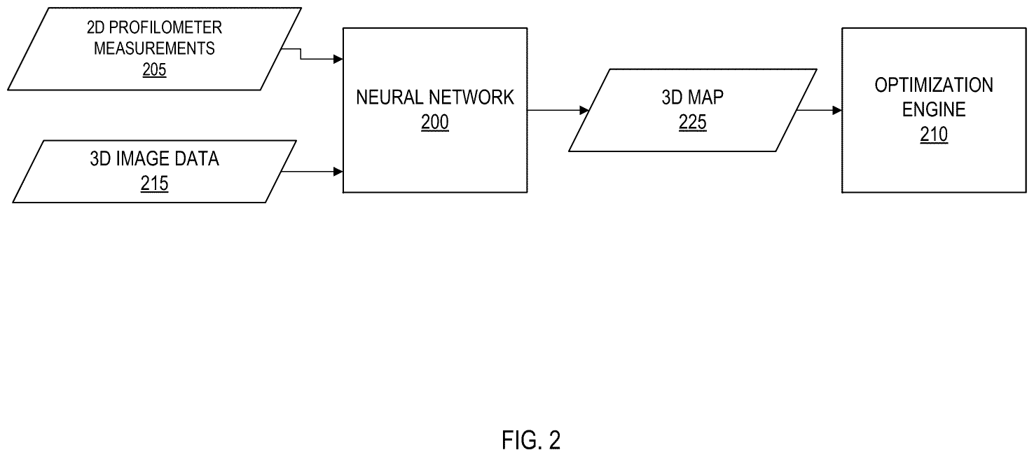

FIG. 1 is a schematic partial top view of a processing chamber 100 configured to perform susceptor alignments, according to one implementation. A transport robot configured to move substrates into and out of the processing chamber 100 may comprise a susceptor 101. The susceptor 101 may comprise a shaft 118 connected to a substrate support 106 that is configured to hold a substrate 102. The susceptor 101 may be configured to move within the processing chamber 100. The transport robot may be controlled by a computing system, such as a computing system that uses the computing components described in FIG. 2. The substrate 102 may be a silicon wafer that is processed inside the processing chamber 100. To position the substrate 102 inside the processing chamber 100, the susceptor 101 may be raised, lowered, tilted, translated, and/or rotated (such as by rotating the substrate support 106 or raising/lowering the shaft). Such positional adjustments may be accomplished automatically (e.g., by the transport robot) or manually (e.g., by a user who makes manual adjustments to components of the susceptor 101 such as the substrate support 106 or the shaft 118).

Processing chamber 100 may comprise processing volume 136, a cavity in which the substrate 102 is processed. Processing chamber 100 may further comprise preheat ring 133. The preheat ring 133 may be configured to surround the susceptor 101. When the susceptor 101 is aligned according to specifications provided by a user, the preheat ring 133 may form a narrow, substantially uniform gap with the edge 125 of the substrate support 106. The substrate support 106 and the preheat ring 133 may each be substantially circular, and the preheat ring 133 may have a larger circumference than the substrate support 106.

Processing chamber 100 may further comprise a heating component 147 such as lamps 141 as shown in FIG. 1. The heating component may be used to process substrate 102 by applying heat to substrate 102. Additionally, processing chamber 100 may comprise a camera system including cameras 153. Furthermore, processing chamber 100 may comprise one or more 2D profilometers, which may be configured to measure a profile between susceptor 101 and preheat ring 133 at various points.

As shown in FIG. 1, the camera system may comprise three cameras 153 that are each configured to capture image data corresponding to susceptor 101 and preheat ring 133. In the example embodiment illustrated in FIG. 1, the cameras 153 also capture depth data because the cameras 153 are positioned at different locations along the circumference of the preheat ring 133. This stereo camera arrangement allows for the capturing of 3D image data (i.e., both image and depth data). Such 3D image data may be processed by a trained neural network in order to create a 3D map of the preheat ring 133 and the susceptor 101, as discussed in further detail below. Although not shown, in alternate embodiments the camera system may comprise a single camera that is configured to travel along the circumference of the preheat ring 133 and capture image data at various points along the circumference, thus enabling the camera to capture 3D image data in a similar manner as a stereo camera system. Other alternate embodiments provide that the camera system comprises a single camera and multiple light sources that are configured to add 3D depth perception to captured image data similar to images captured by stereo camera systems. The camera systems described above are included as example embodiments, and other camera configurations for capturing 3D image data as known in the art may be used as well.

2D profilometer 104 may be any type of 2D profilometer 104 as known in the art, such as a laser-based profilometer. 2D profilometer 104 may be configured to capture measurements of the exact position of the susceptor 101 relative to the preheat ring 133. The 2D profilometer data may offer measurements of a precision within, for example, 5 microns. Each measurement may measure one point along the circumference of the interface between the susceptor 101 and the preheat ring 133. To gather additional 2D profilometer data, the susceptor 101 may be rotated. After the rotation, the 2D profilometer 104 may measure the position of the susceptor 101 relative to the preheat ring 133 again. The rotation and measurement may be repeated to gather additional positional data as necessary for generating a 3D map, as discussed in further detail below with respect to FIG. 2. Taking a higher number of 2D profilometer 104 measurements may result in a more accurate 3D map with a tradeoff of requiring a greater amount of time and resources.

### Example Computing Components for Susceptor Alignment

FIG. 2 illustrates an example of computing components for susceptor alignment. Creating the 3D map 225 may comprise capturing one or more 2D profilometer measurements 205 of the interface between the susceptor 101 and the preheat ring 133 (e.g., by capturing a measurement, rotating the susceptor 101, capturing another measurement, and so on). Additionally, 3D image data 215 (e.g., image data and depth data) may be captured by the camera system. The 3D image data 215 may be provided to a machine learning model such as neural network 200. The 2D profilometer measurements 205 may be provided to the neural network 200 and used as ground truth labels to train the neural network 200 through a supervised learning process. For example, the neural network 200 may generate a mapping of a series of points along the circumference of the interface between the susceptor 101 and the preheat ring 133 based on the 2D profilometer measurements 205. The mapping may comprise detecting edges of the susceptor 101 and the preheat ring 133 based on the 2D profilometer measurements 205. When provided with the 3D image data 215, the neural network 200 may create a preliminary version of the 3D map 225. The creation of the preliminary map may comprise creating two circular profiles based on the detected edges, and then mapping the 3D image data 215 onto the circular profiles to create a preliminary version of the 3D map 225.

The supervised learning process may comprise taking the output of the neural network 200 (e.g., the preliminary version of the 3D map 225), comparing it to the 2D profilometer measurements 205, and then adjusting parameters of the neural network 200 based on differences between the 3D map 225 and the 2D profilometer measurements 205. The susceptor 101 may be rotated, additional 2D profilometer measurements 205 and 3D image data 215 may be taken, updates may be made to the 3D map 225, and the neural network 200 may be retrained for a threshold number of iterations or until the output 3D map 225 matches a threshold number of 2D profilometer measurements 205. Additionally, the supervised learning process may further comprise raising, lowering, tilting, and/or making translational adjustments to the position of the susceptor 101. Making such positional adjustments may allow the 3D map 225 to capture how performing such movements affects the actual position of the susceptor 101. For example, if performing a particular movement with the transport robot causes the susceptor 101 to move to a particular position, the 3D map 225 may store this information. Thus, by using the 3D map 225, a computing system may be able to determine how to move the transport robot in order to cause the susceptor 101 to reach a given positon.

The 3D map 225 may be provided to an optimization engine 210. Optimization engine 210 may comprise one or more processors configured to optimize the position of the susceptor 101 according to specifications provided by a user. For example, the user may specify that the susceptor 101 should be level with the preheat ring 133, and the gap between the susceptor 101 and the preheat ring 133 should be equidistant along the circumference of the interface between the susceptor 101 and the preheat ring 133.

Optimization engine 210 may use an optimization algorithm to adjust the position of the susceptor 101. For example, if the 3D map 225 indicates that a side of the substrate support 106 is tilted upward relative to a specified tilt, the susceptor 101 may be iteratively tilted downward by an increment (e.g., the side of the substrate support 106 may be tilted downward by an increment of 0.01 degrees, or another increment) until the 3D map 225 indicates that the specified tilt is reached; if the 3D map 225 then indicates that the substrate support 106 is tilted downward relative to the specified tilt after an incremental adjustment, the susceptor 101 may be tilted upward by a smaller increment, and so on. As another example, if the 3D map 225 indicates that the gap between the susceptor 101 and the preheat ring 133 is smaller on the left side of the susceptor 101 than on the right side of the susceptor 101, the susceptor 101 may be iteratively moved to the right by an increment (e.g., ten microns, or another increment) until the 3D map 225 indicates that the gap is an equal length on both sides; if the 3D map 225 indicates that the gap is smaller on the right side than on the left after an incremental adjustment, the susceptor 101 may then be moved to the left by a smaller increment, and so on. In alternate embodiments, the optimization engine 210 comprises a machine learning model that is trained to optimize the position of the susceptor 101 based on the 3D map and the position specified by the user.

### Example Views of a Susceptor Relative to a Ring of a Processing Chamber

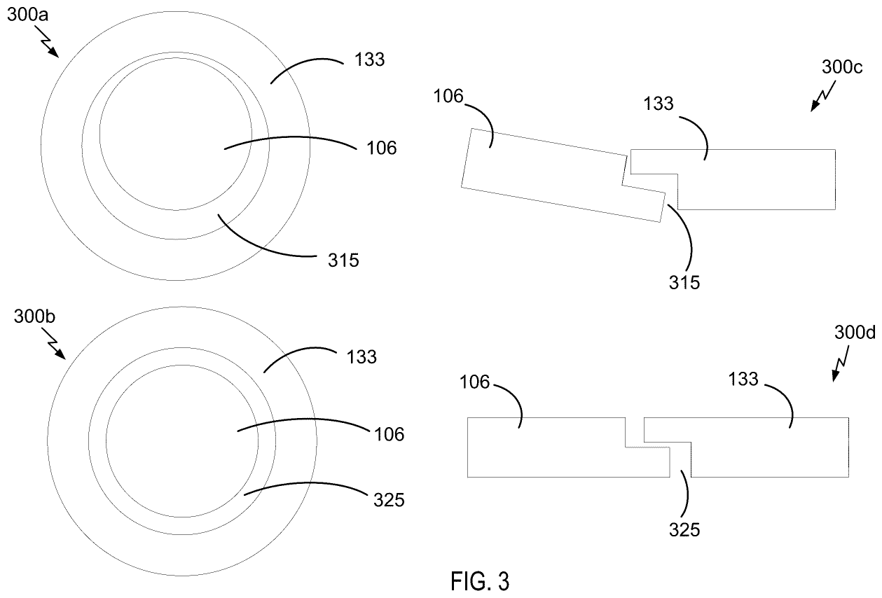

FIG. 3 illustrates example views 300a-d of a susceptor 101 (specifically, the substrate support of the susceptor 101) relative to a preheat ring 133 according to certain embodiments. 300a illustrates a top-down view of a susceptor 101 and a preheat ring 133. In the example shown in 300a, the susceptor 101 is off-center relative to the preheat ring 133. Because the susceptor 101 is off-center, a substrate that is carried by the susceptor 101 may also be off-center relative to the preheat ring 133, resulting in an improperly aligned gap 315. As discussed above, when substrates are improperly positioned within a processing chamber (e.g., off-center relative to the chamber), non-uniformity may occur in the processing results. For example, a temperature gradient may result on the surface of the substrate due to one part of the substrate being too close to a heat source and/or another part of the substrate being too far away from the heat source.

As discussed above, a 3D map of the susceptor 101 and the preheat ring 133 may be generated and used to adjust the positon of the susceptor 101 to a specified position. For example, the specified position may be a position where the gap between the susceptor 101 and the preheat ring 133 is uniform within a specified tolerance, as shown in example 300b. In example 300b, a target gap 325 between the susceptor 101 and the preheat ring 133 is a uniform gap. For example, the target gap 325 of example 300b may be achieved by moving the susceptor 101 of example 300a downward by an increment until the 3D map indicates that the susceptor 101 is located in the center of the preheat ring 133. If an overcorrection occurs (i.e., the susceptor 101 is moved such that the gap is smaller at the bottom than at the top, as indicated by the 3D map), the susceptor 101 may be adjusted upward by a smaller increment until the gap is uniform (or uniform within a specified threshold).
300c illustrates an example where the susceptor 101 is not level with the preheat ring 133. Thus, a substrate that is carried by the susceptor 101 may also not be level with the preheat ring 133. As discussed above, when substrates are improperly positioned within a processing chamber (e.g., not level relative to the chamber), non-uniformity may occur in the processing results. For example, a temperature gradient may result on the surface of the substrate due to one part of the substrate being too close to a heat source and/or another part of the substrate being too far away from the heat source.
300d illustrates an example where the susceptor 101 is level with the preheat ring 133. When the susceptor 101 is level with the preheat ring 133, the target gap 325 may be achieved. The susceptor 101 may be leveled by tilting the side of the susceptor 101 shown in 300c upward by an increment until the 3D map indicates that the susceptor 101 becomes level with the preheat ring 133. If an overcorrection occurs (i.e., the susceptor 101 is tilted such that the susceptor 101 is tilted upward relative to the preheat ring 133, as indicated by the 3D map), the susceptor 101 may be adjusted upward by a smaller increment until the susceptor 101 is level with the preheat ring 133 (or level within a specified threshold).

### Example Operations for Susceptor Alignment

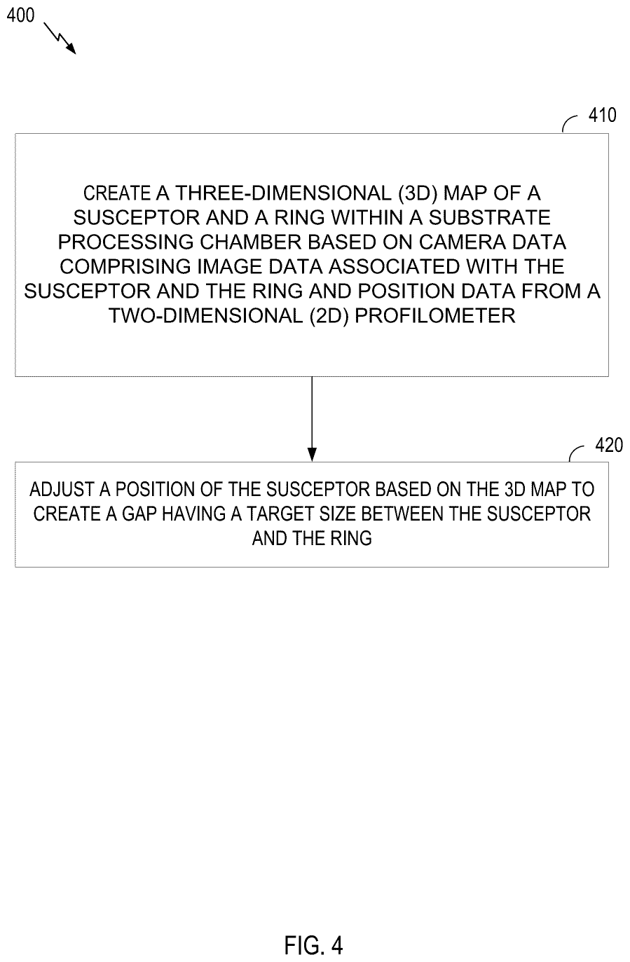

FIG. 4 is a flow diagram of example operations 400 for susceptor alignment. Operations 400 may be performed by a computing device comprising one or more processors, such as the computing device as discussed with respect to FIG. 2.

Operations 400 begin at 410, with creating a three-dimensional (3D) map of a susceptor and a ring within a substrate processing chamber based on camera data comprising image data associated with the susceptor and the ring. In certain embodiments, creating the 3D map is further based on position data received from a two-dimensional (2D) profilometer. Certain embodiments provide that the 3D map is created by a machine learning model that is trained through a supervised learning process involving the position data to create 3D maps. In some embodiments, creating the 3D map is further based on: receiving additional position data from the 2D profilometer after the adjusting of the position of the susceptor; and retraining the machine learning model using the additional position data, wherein the retrained machine learning model is used to update the 3D map. Certain embodiments provide that the supervised learning process comprises iteratively adjusting parameters of the machine learning model until a characteristic of the 3D map matches a characteristic indicated by the position data. In certain embodiments, the supervised learning process comprises iteratively adjusting parameters of the machine learning model based on comparing a characteristic of the 3D map output by the machine learning model in response to the camera data to a characteristic indicated by the position data (e.g., to optimize one or more variables, such as model accuracy, such as via an objective function). In some embodiments, the camera data is provided by a camera system comprising three cameras positioned along a circumference of the ring. According to certain embodiments, the camera data is provided by a camera system comprising a camera configured to move along a circumference of the ring. Some embodiments provide that the camera data is provided by a camera system comprising a camera and multiple light sources, wherein the multiple light sources are configured to allow the camera to capture the depth data.

Operations 400 continue at 420, with adjusting a position of the susceptor based on the 3D map to create a gap having a target size between the susceptor and the ring. According to some embodiments, the gap is created based on using an optimization algorithm to adjust the position of the susceptor based on the 3D map. Some embodiments provide that the gap is created based on using a second machine learning model that is trained to adjust the position of the susceptor based on the 3D map. In certain embodiments, the gap between the susceptor and the ring is substantially equidistant. According to certain embodiments, adjusting the position of the susceptor further comprises adjusting the susceptor so that the susceptor is substantially level with the ring. In some embodiments, the susceptor comprises an arm and a substrate holder, wherein the arm of the susceptor is configured to translate the substrate holder within a substrate processing chamber and tilt the substrate holder in order to create the gap.

While the foregoing is directed to implementations of the present disclosure, other and further implementations of the disclosure may be devised without departing from the basic scope thereof, and the scope thereof is determined by the claims that follow.

What is claimed is:

1. A method of positioning a substrate susceptor, comprising:
creating a three-dimensional (3D) map of a susceptor and a ring within a substrate processing chamber based on camera data comprising image data associated with the susceptor and the ring; and
adjusting a position of the susceptor based on the 3D map to create a gap having a target size between the susceptor and the ring.

2. The method of claim 1, wherein creating the 3D map is further based on position data received from a two-dimensional (2D) profilometer.

3. The method of claim 2, wherein the 3D map is created by a machine learning model that is trained through a supervised learning process involving the position data to create 3D maps.

4. The method of claim 3, wherein creating the 3D map is further based on:
receiving additional position data from the 2D profilometer after the adjusting of the position of the susceptor; and
retraining the machine learning model using the additional position data, wherein the retrained machine learning model is used to update the 3D map.

5. The method of claim 3, wherein the supervised learning process comprises iteratively adjusting parameters of the machine learning model until a characteristic of the 3D map matches a characteristic indicated by the position data.

6. The method of claim 1, wherein the gap is created based on using an optimization algorithm to adjust the position of the susceptor based on the 3D map.

7. The method of claim 1, wherein the gap is created based on using a machine learning model that is trained to adjust the position of the susceptor based on the 3D map.

8. The method of claim 1, wherein the gap between the susceptor and the ring is substantially equidistant.

9. The method of claim 1, wherein adjusting the position of the susceptor further comprises adjusting the susceptor so that the susceptor is substantially level with the ring.

10. The method of claim 1, wherein the susceptor comprises an arm and a substrate holder, wherein the arm of the susceptor is configured to translate the substrate holder within a substrate processing chamber and tilt the substrate holder in order to create the gap.

11. The method of claim 1, wherein the camera data is provided by a camera system comprising three cameras positioned along a circumference of the ring.

12. A method of positioning a substrate susceptor, comprising:
creating a three-dimensional (3D) map of a susceptor and a ring within a substrate processing chamber by:
receiving camera data comprising image data and depth data associated with the susceptor and the ring;
creating the 3D map based on the camera data using a machine learning model trained, based on position data from a two-dimensional (2D) profilometer indicating a location of the susceptor relative to the ring, to create 3D maps;
adjusting the position of the susceptor;
receiving additional position data from the 2D profilometer;
receiving additional camera data; and
retraining the machine learning model using the additional position data,
wherein the retrained machine learning model is used to update the 3D map; and
adjusting the position of the susceptor based on providing the 3D map to an optimization algorithm to create a gap having a target size between the susceptor and the ring.

13. A processing chamber system configured for susceptor alignment, comprising:
a processing chamber for processing substrates;
a susceptor configured to hold a substrate;
a ring;
a camera system configured to capture camera data comprising image data associated with the susceptor and the ring; and
a computing device capable of:
creating a three-dimensional (3D) map of the susceptor and the ring within the substrate processing chamber based on camera data comprising image data associated with the susceptor and the ring; and
adjusting a position of the susceptor based on the 3D map to create a gap having a target size between the susceptor and the ring.

14. The processing chamber system of claim 13, wherein creating the 3D map is further based on position data received from a two-dimensional (2D) profilometer.

15. The processing chamber system of claim 14, wherein the 3D map is created by a machine learning model that is trained through a supervised learning process involving the position data to create 3D maps.

16. The processing chamber system of claim 15, wherein creating the 3D map is further based on:
receiving additional position data from the 2D profilometer after the adjusting of the position of the susceptor; and
retraining the machine learning model using the additional position data, wherein the retrained machine learning model is used to update the 3D map.

17. The processing chamber system of claim 15, wherein supervised learning process comprises iteratively adjusting parameters of the machine learning model until a characteristic of the 3D map matches a characteristic indicated by the position data.

18. The processing chamber system of claim 13, wherein the gap is created based on using an optimization algorithm to adjust the position of the susceptor based on the 3D map.

19. The processing chamber system of claim 13, wherein the gap is created based on using a machine learning model that is trained to adjust the position of the susceptor based on the 3D map.

20. The processing chamber system of claim 13, wherein the susceptor comprises an arm and a substrate holder, wherein the arm of the susceptor is configured to translate the substrate holder within a substrate processing chamber and tilt the substrate holder in order to create the gap.
